(19) United States
(12) Patent Application Publication
(10) Pub. No.: US 2024/0150894 A1
(43) Pub. Date: May 9, 2024

(54) EXHAUST COMPONENT CLEANING METHOD AND SUBSTRATE PROCESSING APPARATUS INCLUDING EXHAUST COMPONENT

(71) Applicant: ASM IP Holding B.V., Almere (NL)

(72) Inventors: Toshiharu Watarai, Tokyo (JP); Hiroki Arai, Tokyo (JP); Toshio Nakanishi, Tokyo (JP); Yoshiyuki Kikuchi, Tokyo (JP); Ryo Miyama, Tokyo (JP)

(21) Appl. No.: 18/413,533

(22) Filed: Jan. 16, 2024

Related U.S. Application Data
(63) Continuation of application No. 17/010,561, filed on Sep. 2, 2020.
(60) Provisional application No. 62/897,243, filed on Sep. 6, 2019.

(51) Int. Cl. C23C 16/44; C23C 16/455; C23C 16/50; H01J 37/32

(52) U.S. Cl. CPC C23C 16/4405; C23C 16/4412; C23C 16/45591; C23C 16/50; H01J 37/32834; H01J 37/32853; H01J 37/32862; H01J 37/3288

(57) ABSTRACT

Examples of a cleaning method includes supplying a cleaning gas into an exhaust duct that provides an exhaust flow passage of a gas supplied to an area above a susceptor, the exhaust duct having a shape surrounding the susceptor in plan view, and activating the cleaning gas to clean an inside of the exhaust duct.

### CROSS-REFERENCE TO RELATED APPLICATIONS

This application is a continuation of, and claims priority to, U.S. patent application Ser. No. 17/010,561, filed Sep. 2, 2020 and entitled “EXHAUST COMPONENT CLEANING METHOD AND SUBSTRATE PROCESSING APPARATUS INCLUDING EXHAUST COMPONENT,” which is a nonprovisional of, and claims priority to, U.S. Provisional Patent Application No. 62/897,243, filed on Sep. 6, 2019, in the United States Patent and Trademark Office, the disclosures of which are hereby incorporated by reference herein.

### TECHNICAL FIELD

Examples are described which relate to an exhaust component cleaning method and a substrate processing apparatus including an exhaust component.

### BACKGROUND

A plasma CVD apparatus includes a chamber for forming a film on a substrate by means of CVD, and an exhaust component used for discharge of a gas inside a chamber. As a result of operation of the plasma CVD apparatus, an unwanted film or by-product is formed in the chamber and the exhaust component. In order to remove such unwanted film or by-product, dry cleaning using plasma is performed on a regular basis. Such cleaning requires a long time and thus lowers productivity of the CVD apparatus. Also, the plasma for cleaning is supplied to the exhaust component through the chamber and thus may be deactivated by the time the plasma reaches the exhaust component. Therefore, cleaning of the exhaust component is difficult and time-consuming.

### SUMMARY

Some examples described herein may address the above-described problems. Some examples described herein may provide a cleaning method for efficiently cleaning an exhaust component, and a substrate processing apparatus that enables efficient cleaning of an exhaust component.

In some examples, a cleaning method includes supplying a cleaning gas into an exhaust duct that provides an exhaust flow passage of a gas supplied to an area above a susceptor, the exhaust duct having a shape surrounding the susceptor in plan view, and activating the cleaning gas to clean an inside of the exhaust duct.

### BRIEF DESCRIPTION OF THE DRAWINGS

FIG. 1 is a sectional view of a substrate processing apparatus;

FIG. 2 is an enlarged partial view of FIG. 1;

FIG. 3 is a plan view of the susceptor and the exhaust duct;

FIG. 4 is a timing chart illustrating an example of an exhaust component cleaning method;

FIG. 5 is a partial sectional view of a substrate processing apparatus according to another example;

FIG. 6 is a partial sectional view of a substrate processing apparatus according to still another example;

FIG. 7 is a sectional view of a substrate processing apparatus according to another example;

FIG. 8 is a timing chart indicating an example of a cleaning method;

FIG. 9 is a diagram illustrating an example configuration of a substrate processing apparatus according to another example;

FIG. 10 is a timing chart indicating an example of a cleaning method;

FIG. 11 is a photo of the inside of an exhaust component;

FIG. 12 is another photo of the inside of an exhaust component;

FIG. 13 is still another photo of the inside of an exhaust component; and

FIG. 14 shows an experimental result.

### DETAILED DESCRIPTION

Examples of an exhaust component cleaning method and a substrate processing apparatus including an exhaust component will be described with reference to the drawings. Components that are the same or correspond to each other are provided with a same reference numeral and repetitive description thereof may be omitted.

### Embodiment

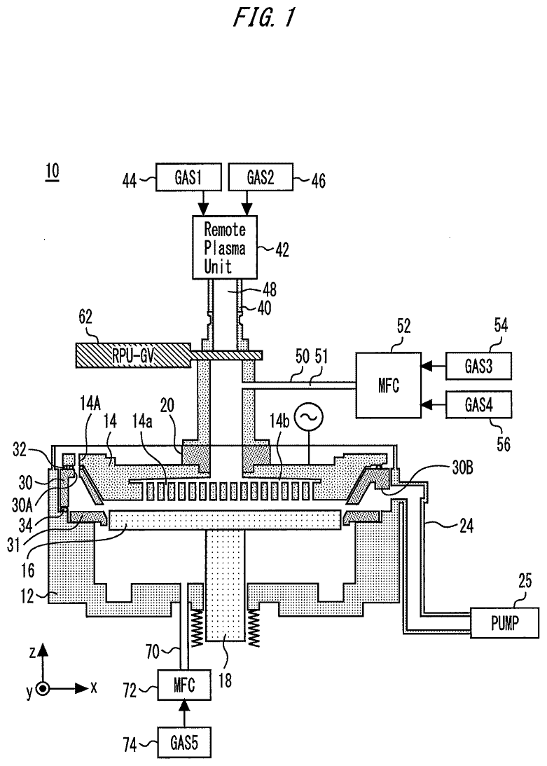

FIG. 1 is a sectional view illustrating an example configuration of a substrate processing apparatus 10. The substrate processing apparatus 10 includes a chamber (Reactor Chamber) 12. In the chamber 12, a susceptor 16 is provided. In an example, the susceptor 16 is heated by an incorporated heater or an external heater and thereby can control a temperature of a substrate. The susceptor 16 is supported by a sliding shaft 18. The susceptor 16 is, for example, electrically connected to the chamber 12 and thereby is grounded. A shower head 14 that faces the susceptor 16 is provided above the susceptor 16. A plurality of slits 14a are formed in the shower head 14. The shower head 14 provides a diffusion space 14b that communicates with the plurality of slits 14a. The susceptor 16 and the shower head 14 jointly provide a parallel plate structure.

In an example, an exhaust piping 24 is provided at a side surface of the chamber 12. The exhaust piping 24 is provided for discharging a raw material gas, etc., used in substrate processing such as film formation in the chamber 12. Therefore, a vacuum pump 25 is connected to the exhaust piping 24.

The susceptor 16 is surrounded by an exhaust duct 30 having a shape surrounding the susceptor 16 in plan view. The exhaust duct 30 is formed of, for example, ceramic. In another example, the exhaust duct 30 can be an insulator. The exhaust piping 24 provides an exhaust channel that communicates with the inside of the exhaust duct 30. An O-ring 32 is provided between the exhaust duct 30 and the shower head 14. The O-ring 32 is adequately compressed as a result of being sandwiched between the exhaust duct 30 and the shower head 14. The shower head 14 is placed on the exhaust duct 30 via the O-ring 32. An O-ring 34 is provided between the exhaust duct 30 and the chamber 12. The O-ring 34 is adequately compressed as a result of being sandwiched between the exhaust duct 30 and the chamber 12. The exhaust duct 30 is placed on the chamber 12 via the O-ring 34. In an example, the exhaust duct 30 has two roles. A first role is to electrically separate the shower head 14 to which power is applied and the chamber 12 having a GND potential from each other. A second role is to guide a gas supplied to the chamber 12 to the exhaust piping 24.

In an example, a through-hole 30A is provided in an upper portion of the exhaust duct 30 and a through-hole 14A is provided in the shower head 14. The through-hole 30A and the through-hole 14A communicate with each other. A flow control ring (FCR) 31 placed on the chamber 12 is provided below the exhaust duct 30. The FCR 31 has an annular shape surrounding the susceptor 16. A gas used in substrate processing travels into the exhaust duct 30 from between the FCR 31 and the exhaust duct 30.

A transport tube 40 is connected to the shower head 14 via an insulation component 20. The transport tube 40 is a tube extending in a z-direction, that is, a substantially vertical direction. The transport tube 40 provides a substantially vertical flow passage that communicates with a diffusion space 14b above the slits 14a.

A remote plasma unit (RPU) 42 is provided at an upper end of the transport tube 40. Gas sources 44, 46 that supply a cleaning gas to be used for cleaning of the chamber 12, etc., are connected to the RPU 42. The gases supplied from the gas sources 44, 46 to the RPU 42 are brought into a plasma state or activated by the RPU 42 and thereby turn into a reactive species. The reactive species is used for cleaning of the chamber 12, etc. The gases stored in the gas sources 44, 46 are, for example, Ar and NF₃.

A gas supply line 50 is connected to a side surface of the transport tube 40 substantially perpendicularly to the transport tube 40. The gas supply line 50 provides a flow passage 51 that communicates with a space 48 in the transport tube 40. A mass flow controller (MFC) 52 is connected to the gas supply line 50. Gas sources 54, 56 are connected to the MFC 52. For example, the gas sources 54, 56 are ones for supplying gases to be used for film formation. For example, the gas sources 54, 56 provide an O₂ gas and a TEOS gas. The gases from the gas sources 54, 56 are subjected to pressure control by the MFC 52 and supplied to the flow passage 51, and travels through the inside of the flow passage 51 substantially horizontally and reaches the space 48 in the transport tube 40.

An RPU gate valve 62 is connected to the side surface of the transport tube 40. Upon the RPU gate valve 62 being closed, the RPU 42 and the chamber 12 are shut off from each other, enabling preventing a cleaning gas from being mixed into a raw material gas.

A gas supply tube 70 is connected to a bottom portion of the chamber 12. An MFC 72 is connected to the gas supply tube 70. A gas source 74 is connected to the MFC 72. The gas source 74 provides, for example, an O₂ gas. For example, in order to suppress travel of a gas to an area below the susceptor 16, the gas being provided to an area above the susceptor 16 via the slits 14a, a gas from the gas source 74 is subjected to pressure control by the MFC 72 and supplied to the area below the susceptor 16 through the gas supply tube 70.

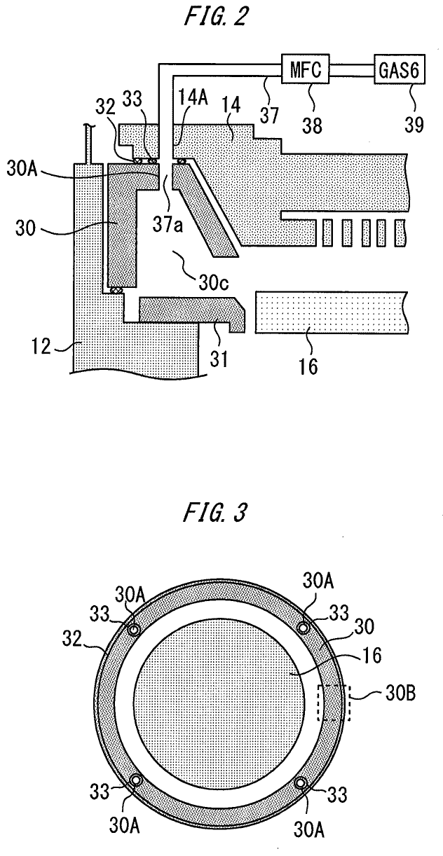

FIG. 2 is an enlarged partial view of FIG. 1. In an example, a piping 37 that communicates with the through-hole 14A and the through-hole 30A is fixed to an upper surface of the shower head 14. In another example, a piping 37 that communicates with the through-hole 30A can be fixed to the upper surface of the exhaust duct 30. An MFC 38 and a cleaning gas source 39 are connected to the piping 37. A cleaning gas is stored in the cleaning gas source 39. The cleaning gas can contain, for example, at least one of an O₂ gas, an NF₃ gas and an SF₆ gas. For example, an activated O₂ gas enables removal of a carbon-based film and each of an activated NF₃ gas and an activated SF₆ gas enables removal of a Si-based film.

As an example of a cleaning gas supply configured to provide a cleaning gas into the exhaust duct 30, the cleaning gas source 39, the piping 37 that supplies a gas from the cleaning gas source 39 to the through-hole 30A, and the MFC 38 are provided.

FIG. 3 is a plan view of the susceptor 16 and the exhaust duct 30. A plurality of through-holes 30A can be provided in the exhaust duct 30. In the example in FIG. 3, four through-holes 30A are provided at equal intervals. Consequently, a cleaning gas can be provided to the exhaust duct 30 from the plurality of through-holes 30A. In another example, different number and different arrangement of through-holes 30A can be employed. The O-ring 32 has a shape surrounding the susceptor 16 in plan view and is provided on an upper surface of the exhaust duct 30. O-rings 33 each have a shape surrounding the corresponding through-hole 30A and are provided on the upper surface of the exhaust duct 30. As illustrated in FIG. 1, a part 30B of the annularly provided exhaust duct 30 has a shape, an outer wall of which is cut out. The part 30B of the exhaust duct 30 connects a space in the exhaust duct 30 and a flow passage of the exhaust piping 24 to each other.

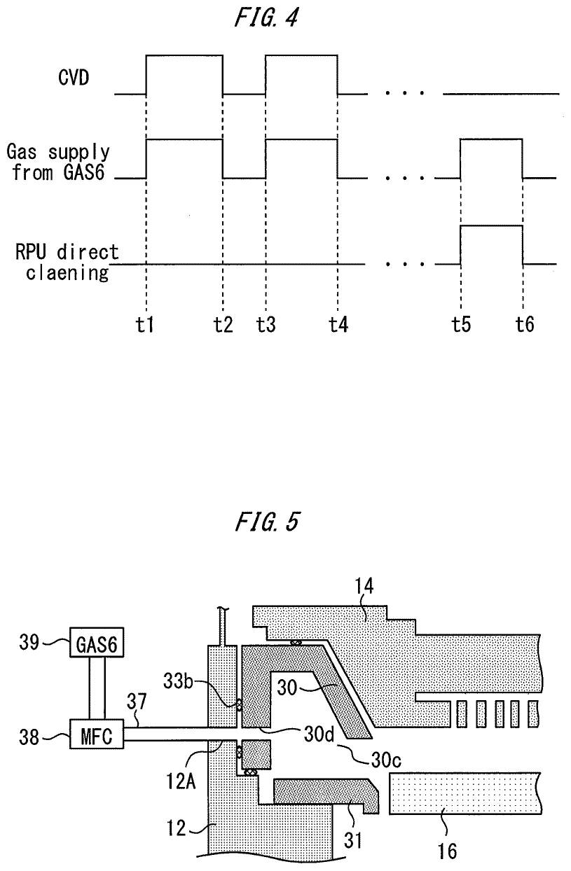

FIG. 4 is a timing chart illustrating an example of an exhaust component cleaning method using the substrate processing apparatus. In this example, during times t1 to t2, a film is formed on a substrate provided on the susceptor 16 by means of CVD. For example, while a raw material gas and a reactant gas are provided from the gas sources 54, 56 into between the susceptor 16 and the shower head 14 through the diffusion space 14b and the slits 14a, process plasma for subjecting the substrate to processing is generated by application of high-frequency power to the shower head 14. The gas provided from the shower head 14 to the area above the susceptor 16 may be a known process gas. Although in this example, a film is formed on a substrate using process plasma, a substrate can be etched or reformed using process plasma.

While process plasma is generated as described above and a substrate is subjected to processing, a cleaning gas is provided to the space 30c in the exhaust duct 30 from the cleaning gas source 39 through the piping 37, the through-hole 14A and the through-hole 30A. Since the exhaust duct 30 provides an exhaust flow passage of a gas supplied to the area above the susceptor 16, process plasma that is not completely deactivated enters the space 30c. Then, the cleaning gas provided from the cleaning gas source 39 is activated by the process plasma in the exhaust duct 30. The activated cleaning gas cleans the inside of the exhaust duct 30 and is discharged through the exhaust piping 24. The activated cleaning gas can clean not only the exhaust duct 30 but also the exhaust piping 24.

As described above, in the period of the times t1 to t2, while a substrate is processed using process plasma, exhaust duct 30 is cleaned using the process plasma and a cleaning gas. Therefore, there is no waiting time for substrate processing due to cleaning.

During times t2 to t3, the processing object substrate is replaced with another or a gaseous species to be provided into between the parallel flat plates is changed. During times t3 to t4, as in the period of the times t1 to t2, while the substrate is processed using process plasma, the exhaust duct 30 is cleaned. Such processing above is repeated a given number of times.

In a period of times t5 to t6, direct cleaning is performed. In the direct cleaning, either provision of gases from the gas sources 54, 56 to the chamber nor application of high-frequency power to the shower head is performed. In the direct cleaning, the RPU gate valve 62 is opened to supply a chamber cleaning gas activated by plasma energy from the RPU 42 to the area above the susceptor 16 through the shower head 14. Consequently, the inside of the chamber 12 can be cleaned. The activated chamber cleaning gas is discharged through the exhaust duct 30 and the exhaust piping 24. Here, a cleaning gas is provided to the space 30c in the exhaust duct 30 from the cleaning gas source 39. Then, the cleaning gas is activated by the chamber cleaning gas in the exhaust duct 30 and cleans the exhaust duct 30. The activated cleaning gas can also clean the exhaust piping 24.

In an example that is different from FIG. 4, only either provision of a cleaning gas from the cleaning gas source 39 in the periods of t1 to t2 and t3 to t4 or provision of the cleaning gas in the period of t5 to t6 can be performed. In other words, in the periods of t1 to t2 and t3 to t4, a cleaning gas is not provided from the cleaning gas source 39 and in the period of t5 to t6, the cleaning gas is provided, whereby the exhaust duct 30 and the exhaust piping 24 can be cleaned. Alternatively, in the period of t5 to t6, a cleaning gas is not provided from the cleaning gas source 39 and in the periods of t1 to t2 and t3 to t4, the cleaning gas is provided, whereby the exhaust duct 30 and the exhaust piping 24 can be cleaned.

FIG. 5 is a partial sectional view of a substrate processing apparatus according to another example. A through-hole 30d is formed in a side wall of an exhaust duct 30 in FIG. 5. A through-hole 12A that communicates with the through-hole 30d is provided in a chamber 12. In order to prevent a space between the exhaust duct 30 and the chamber 12 from communicating the through-hole 30d and the through-hole 12A, an O-ring 33b is provided in a state in which the O-ring 33b is compressed by the exhaust duct 30 and the chamber 12. A piping 37 is connected to a side wall of the chamber 12 so as to communicate with the through-hole 12A and the through-hole 30d. A cleaning gas is supplied into the exhaust duct 30 via the piping 37, the through-hole 12A and the through-hole 30d. A plurality of pairs of a through-hole 30d and a through-hole 12A may be provided to supply a cleaning gas to the exhaust duct 30 from a plurality of channels.

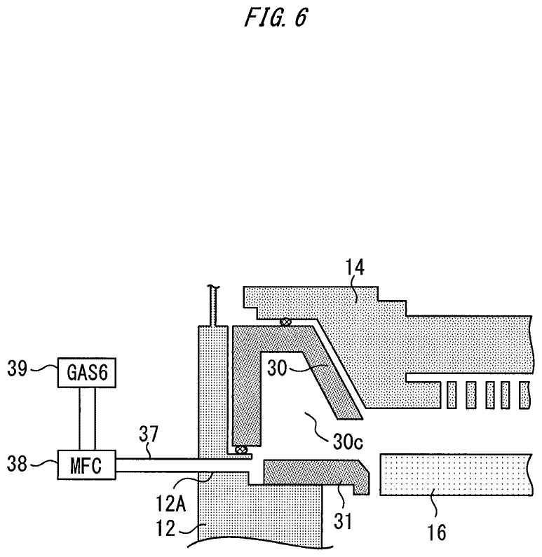

FIG. 6 is a partial sectional view of a substrate processing apparatus according to another example. A through-hole 12A is provided in a chamber 12 in FIG. 6. A piping 37 is connected to a side wall of the chamber 12 so as to communicate with the through-hole 12A. A cleaning gas is supplied into an exhaust duct 30 via the piping 37 and the through-hole 12A. More specifically, a cleaning gas is supplied into the exhaust duct 30 from between the exhaust duct 30 and an FCR 31. A plurality of through-holes 12A may be provided to supply a cleaning gas to the exhaust duct 30 from a plurality of channels.

In both of the examples in FIGS. 5 and 6, a cleaning gas supplied into the exhaust duct 30 is activated by process plasma or activated by a chamber cleaning gas activated by the RPU 42 and cleans the exhaust duct 30 and the exhaust piping 24. Although as example configurations that each enable supply of a cleaning gas to the exhaust duct 30, the configurations illustrated in FIGS. 2, 5 and 6 are indicated, another configuration may be employed.

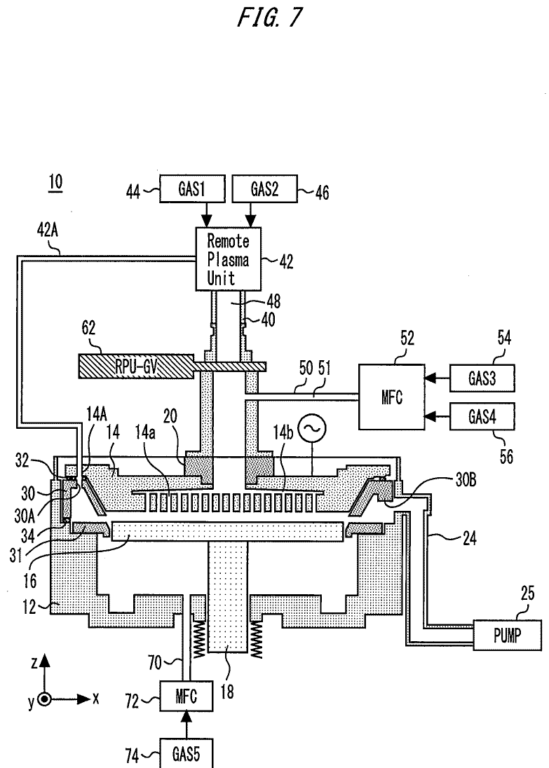

FIG. 7 is a sectional view of a substrate processing apparatus according to another example. The substrate processing apparatus includes a piping 42A that supplies a gas from an RPU 42 into a through-hole 30A of an exhaust duct 30. In this example, the RPU 42 and the piping 42A are provided as a cleaning gas supply. This configuration enables supply of a cleaning gas activated by plasma from the RPU 42 to the exhaust duct 30 via the piping 42A, a through-hole 14A and through-hole 30A and thus enables cleaning of the exhaust duct 30 and an exhaust piping 24.

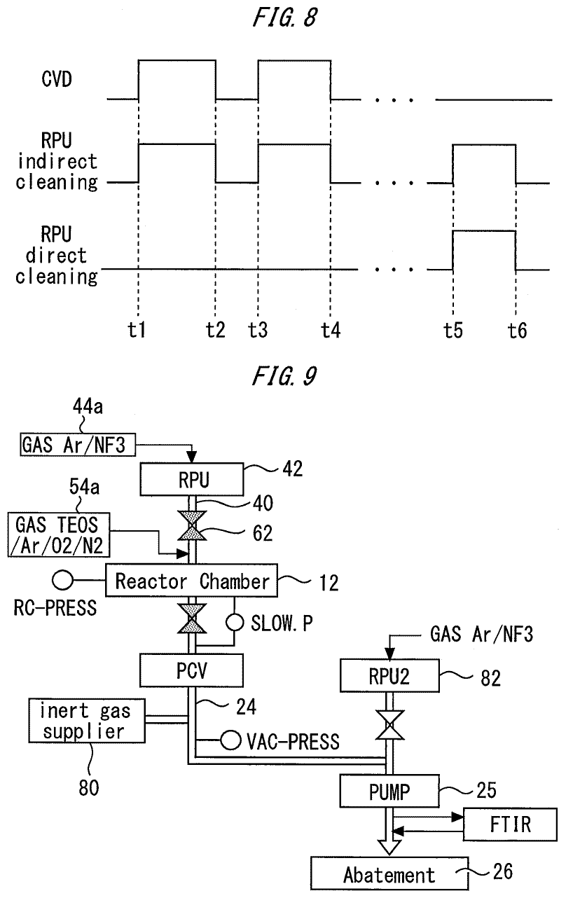

FIG. 8 is a timing chart indicating an example of a cleaning method using the apparatus in FIG. 7. In CVD film formation periods of times t1 to t2 and times t3 to t4, while an RPU gate valve 62 is closed, a cleaning gas activated by the RPU 42 is supplied into the exhaust duct 30 through the piping 42A. The cleaning gas supplied into the exhaust duct 30 cleans the exhaust duct 30 and the exhaust piping 24 and is then discharged. The cleaning of the exhaust duct 30 and the exhaust piping 24 is stated as “RPU indirect cleaning” in FIG. 8. Furthermore, in a direct cleaning period of times t5 to t6, RPU indirect cleaning may be performed. It is also possible to perform only either RPU indirect cleaning in a CVD film formation period or RPU indirect cleaning in a direct cleaning period.

FIG. 9 is a diagram illustrating an example configuration of a substrate processing apparatus according to another example. As in the configuration in FIG. 1, an exhaust duct and a susceptor are provided inside a chamber 12. An inert gas supplier 80 is connected to an exhaust component that provides an exhaust flow passage of a gas supplied to the chamber 12. In this example, the inert gas supplier 80 is connected to an intermediate point in an exhaust piping 24. The inert gas supplier 80 supplies an inert gas to the exhaust piping 24. In order to adjust a flow of the gas supplied from the inert gas supplier 80, an MFC can be provided. The inert gas supplied from the inert gas supplier 80 can contain at least one of Ar, N₂ and He. In an example, a first gas source 44a supplies an NF₃ gas to an RPU 42 as a chamber cleaning gas and a second gas source 54a supplies, for example, TEOS to the chamber 12.

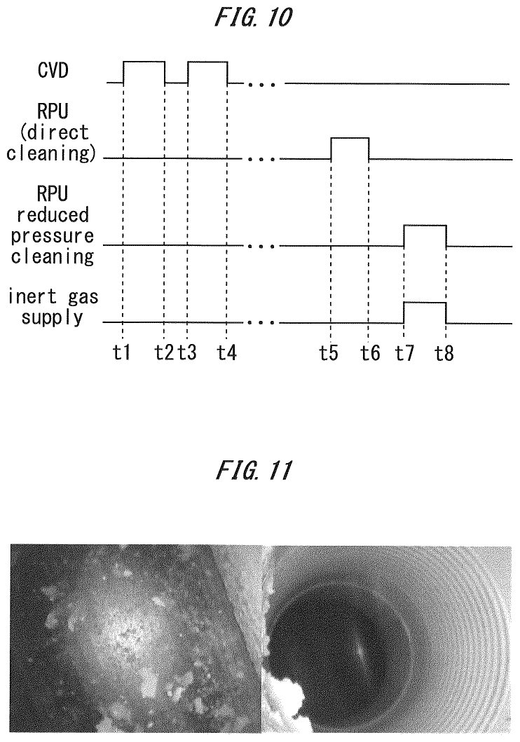

FIG. 10 is a timing chart indicating a method of use of the substrate processing apparatus in FIG. 9. In a period of times t1 to t2, a raw material gas, for example, TEOS and a reactant gas are supplied into the chamber from the second gas source 54a and high-frequency power is applied to a shower head to subject a substrate to processing. During times t3 to t4, also, substrate processing that is similar to the above is performed. As the substrate processing, firm formation, etching or firm reforming may be performed. An example of the substrate processing is a thick firm formation process using a large amount of raw material gas. An example of the thick firm formation process is a process of supplying 10 g/min or more of TEOS to the shower head to form an oxide film having a thickness of 5 μm or more on a wafer. That process is employed, for example, in a process of manufacturing a 3D NAND flash memory device. Use of a large amount of a raw material gas such as TEOS is likely to cause generation of a great amount of powder by-product. The by-product may cause occlusion of the exhaust piping 24, a vacuum pump 25 and an abatement 26.

After repetition of substrate processing a predetermined number of times, direct cleaning is performed during times t5 to t6. In the direct cleaning, an RPU gate valve 62 is opened and a chamber cleaning gas activated by plasma energy from an RPU 42 is supplied to an area above a susceptor 16 through a shower head 14. Consequently, mainly the inside of the chamber 12 is cleaned. In an example, the direct cleaning can be terminated after confirmation of an emission intensity peak of SiF₄ generated from a film remainder by Ar plasma generated by application of high-frequency power to a shower plate being sufficiently lowered.

A period of times t7 to t8 is an exhaust flow passage cleaning period. In an exhaust flow passage cleaning period, pressure inside the chamber 12 is reduced and a cleaning gas activated by the RPU 42 is supplied to the exhaust piping 24 through the inside of the chamber 12. This is expressed by the term “RPU reduced pressure cleaning” in FIG. 10. In an example, the pressure inside the chamber 12 in the exhaust flow passage cleaning period can be made to be no more than 470 Pa. Furthermore, during times t7 to t8, an inert gas is supplied from the inert gas supplier 80 to the exhaust piping 24. The inert gas, and the cleaning gas travelling from the chamber 12 to the exhaust piping 24 are discharged by the vacuum pump 25.

In an exhaust flow passage cleaning period, reducing the pressure inside the chamber to, for example, no more than 470 Pa enables suppression of retention of a cleaning gas in the chamber 12 and thus enables conveyance of a larger amount of active species to the downstream of the exhaust piping 24. In an example, the active species is an NF₃ radical. If the pressure inside the chamber is excessively lowered, the RPU 42 fails to normally operate, and if the pressure inside the chamber is raised, efficiency of cleaning the inside of the chamber is increased. The pressure inside the chamber is determined in consideration of these points.

An inert gas in a neutral state, which is not a radical, is supplied from the inert gas supplier 80 to the exhaust piping 24. This inert gas conveys a radical as a carrier gas. The inert gas contributes to conveyance of an active species such as an F radical to the downstream of the exhaust piping 24 as it is in an active state. Therefore, a by-product in each of the exhaust piping 24, the vacuum pump 25 and the abatement 26 can be removed or reduced. In another example, an active species can quickly be guided to the exhaust piping 24 by supplying an inert gas from the inert gas supplier 80 into the chamber 12.

After an end of the process up to the time t8, substrate processing is resumed. The order of the direct cleaning during the times t5 to t6 and the exhaust flow passage cleaning period during the times t7 to t8 may be reversed. In direct cleaning performed before or after an exhaust flow passage cleaning period, no inert gas is supplied to the exhaust piping 24, the pressure in the chamber 12 is made to be higher than the pressure in the chamber 12 in the exhaust flow passage cleaning period and a cleaning gas activated by the RPU 42 is supplied to the chamber 12. Consequently, the inside of the chamber 12 is mainly cleaned. In direct cleaning, for example, the pressure inside the chamber is made to be around 1000 Pa.

FIG. 11 includes a photo of the inside of a pump and a photo of the inside of an exhaust piping where only direct cleaning was performed and no exhaust flow passage cleaning period was provided. In this case, a large amount of by-product can be recognized.

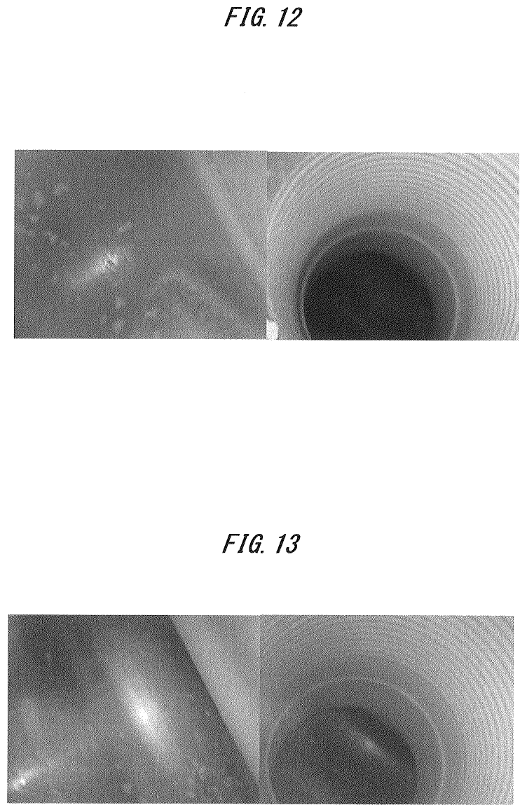

FIG. 12 includes a photo of the inside of the pump and a photo of the inside of the exhaust piping where the pressure inside the chamber 12 was reduced to 470 Pa and a cleaning gas activated by the RPU 42 was supplied to the exhaust piping 24 through the inside of the chamber 12. In this example, no inert gas was supplied from the inert gas supplier 80 to the exhaust piping 24. In this case, a by-product can be suppressed more in comparison with FIG. 11.

FIG. 13 includes a photo of the inside of the pump and a photo of the inside of the exhaust piping after the above-described exhaust flow passage cleaning period. In this example, the pressure inside the chamber 12 was reduced to 470 Pa and a cleaning gas activated by the RPU 42 was supplied to the exhaust piping 24 through the inside of the chamber 12. Also, 20 slm of Ar was supplied from the inert gas supplier 80 to the exhaust piping 24. In this case, a by-product can be suppressed more in comparison with FIGS. 11 and 12.

In each of the examples in FIGS. 11 to 13, 4.75 slm of NF₃ was supplied from the first gas source 44a and 5.00 slm of Ar was supplied from the second gas source 54a. Also, the photos in FIGS. 11 to 13 were ones taken after cleaning subsequent to successive formation of a film on 100 substrates.

In a test that is different from the test from which the photos in FIGS. 11 to 13 were obtained, film formation and NF₃ radical cleaning using the RPU 42 were repeated 100 times in the order mentioned, NF₃ radical cleaning was performed by the RPU 82, and SiF₄, which is a decomposition product of residue by-product SiO₂, was detected by an FTIR installed in an exhaust line. Detection of a larger amount of decomposition product SiF₄ means that there are a larger amount of residue by-product in the pump and the vicinity thereof.

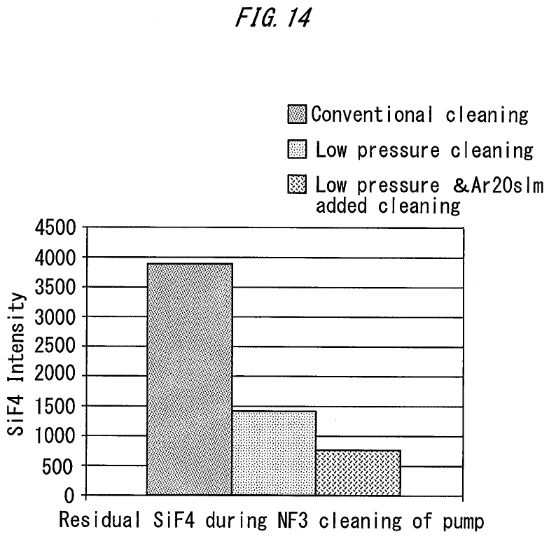

FIG. 14 is a graph indicating an SiF₄ spectrum intensity obtained in the above described test. “Conventional cleaning” indicates a result of only direct cleaning being performed. It can be seen that in the conventional cleaning, there were a large amount of decomposition product SiF₄ and a residue by-product was not sufficiently removed. “Low pressure cleaning” indicates a result of the pressure inside the chamber 12 being reduced to 470 Pa and a cleaning gas activated by the RPU 42 being provided to the exhaust piping 24 through the inside of the chamber 12. In the low pressure cleaning, no inert gas was supplied from the inert gas supplier 80 to the exhaust piping 24. The residue SiF₄ amount in the low pressure cleaning was 36% of the residue SiF₄ amount in the conventional cleaning. “Low pressure & Ar 20 slm added cleaning” indicates a result of cleaning performed in the above-described exhaust flow passage cleaning period. In the low pressure & Ar 20 slm added cleaning, in addition to the conditions for the low pressure cleaning, 20 slm of Ar was supplied from the inert gas supplier 80 to the exhaust piping 24. The residue SiF₄ amount in the low pressure & Ar 20 slm added cleaning was 20% of the residue SiF₄ amount in the conventional cleaning.

The cleaning method described above in each of the examples particularly enhances efficiency of cleaning an exhaust component. The exhaust duct 30 and the exhaust piping 24 are examples of the exhaust component. Another exhaust component that is different from the exhaust duct 30 and the exhaust piping 24 may be provided. Examples of the exhaust component may include a bellows, a pump and an abatement.

1. A cleaning method comprising:
supplying a cleaning gas into an exhaust duct that provides an exhaust flow passage of a gas supplied to an area above a susceptor, the exhaust duct having a shape surrounding the susceptor in plan view; and
activating the cleaning gas to clean an inside of the exhaust duct.

2. The cleaning method according to claim 1, comprising generating process plasma that subjects a substrate provided on the susceptor to processing, by applying high-frequency power to a shower head provided above the susceptor so as to face the susceptor, while providing a process gas to the area above the susceptor,
wherein the cleaning gas is activated by the process plasma in the exhaust duct.

3. The cleaning method according to claim 1, comprising supplying the cleaning gas into the exhaust duct after activation of the cleaning gas by a remote plasma unit.

4. The cleaning method according to claim 1, comprising supplying a chamber cleaning gas activated by a remote plasma unit to the area above the susceptor via a shower head provided above the susceptor so as to face the susceptor,
wherein the cleaning gas is activated by the chamber cleaning gas in the exhaust duct.

5. The cleaning method according to claim 1, wherein the cleaning gas is supplied into the exhaust duct via a through-hole formed in an upper portion of the exhaust duct.

6. The cleaning method according to claim 1, wherein the cleaning gas is supplied into the exhaust duct via a through-hole formed in a side wall of the exhaust duct.

7. The cleaning method according to claim 1, wherein the cleaning gas is supplied into the exhaust duct via a through-hole formed in a chamber covering the susceptor and the exhaust duct.

8. The cleaning method according to claim 1, wherein the cleaning gas contains at least one of an O₂ gas, an NF₃ gas and an SF₆ gas.

9. A cleaning method comprising supplying an inert gas into an exhaust flow passage that communicates with a chamber, while suppling a cleaning gas activated by a remote plasma unit into the exhaust flow passage through an inside of the chamber.

10. The cleaning method according to claim 9, comprising making pressure inside the chamber in an exhaust flow passage cleaning period in which the inert gas is supplied to the exhaust flow passage be no more than 470 Pa.

11. The cleaning method according to claim 9, comprising making pressure in the chamber be higher than the pressure in the chamber in an exhaust flow passage cleaning period in which the inert gas is supplied to the exhaust flow passage and supplying the cleaning gas activated by the remote plasma unit to the chamber without supplying the inert gas to the exhaust flow passage, before or after the exhaust flow passage cleaning period.

12. A substrate processing apparatus comprising:
a susceptor;
a showerhead above the susceptor;
an exhaust duct surrounding the susceptor in plan view;
an exhaust piping that provides an exhaust route communicating with an inside of the exhaust duct;
a cleaning gas source, wherein the cleaning gas source is a source of at least one of O₂ gas, an NF₃ gas, and an SF₆ gas, and
a piping that connects the cleaning gas source to the exhaust duct through a cleaning gas hole within the showerhead and a through-hole in an upper surface of the exhaust duct.

13. The substrate processing apparatus according to claim 12, wherein the upper surface of the exhaust duct comprises a plurality of through-holes.

14. The substrate processing apparatus according to claim 12, wherein the cleaning gas source supplies the gas to a remote plasma unit before it is supplied to the exhaust duct.

15. The substrate processing apparatus of claim 12, wherein
the upper surface of the exhaust duct comprises four through-holes provided at equal intervals.

16. The substrate processing apparatus according to claim 12, wherein the exhaust duct is sealably coupled to the showerhead and to a chamber of the substrate processing apparatus.

17. A substrate processing apparatus comprising:
a first remote plasma unit;
a chamber connected to the remote plasma unit;
a susceptor provided in the chamber;
an exhaust component that provides an exhaust flow passage of a gas supplied to the chamber;
a pressure control valve disposed between the chamber and the exhaust component;
a second remote plasma unit and a second remote plasma unit gas source, wherein the second remote plasma unit gas source is fluidly connected to the second remote plasma unit, wherein the second remote plasma unit is fluidly connected to the exhaust piping downstream of the pressure control valve; and
an inert gas supplier connected to the exhaust component downstream of the pressure control valve,
wherein the inert gas supplier supplies an inert gas to the exhaust flow passage,
wherein the exhaust component comprises an exhaust piping,
wherein the inert gas supplier is connected to an intermediate portion of the exhaust piping, and
wherein the inert gas supplier is fluidly connected to the chamber through the exhaust piping.

18. The substrate processing apparatus according to claim 17, comprising a first gas source fluidly connected to the first remote plasma unit, wherein the first gas source is a source of an NF₃ gas.

19. The substrate processing apparatus according to claim 17, comprising a second gas source fluidly connected to the chamber, wherein the second gas source is a source of TEOS.

20. The substrate processing apparatus according to claim 17, wherein the second remote plasma unit gas source is a source of NF₃.
